(19) United States
(12) Patent Application Publication
(10) Pub. No.: US 2012/0088047 A1
(43) Pub. Date: Apr. 12, 2012

(54) HOUSING AND METHOD FOR MANUFACTURING SAME

(75) Inventors: YANG-TAO LEI, Shenzhen City (CN); HUAN-BING YE, Shenzhen City (CN); ZHONG-TAO BI, Shenzhen City (CN); CHUAN CHEN, Shenzhen City (CN); XUE-YUN ZU, Shenzhen City (CN); CHANG-SHUI HU, Shenzhen City (CN)

(73) Assignees: FIH (HONG KONG) LIMITED, Kowloon (HK); SHENZHEN FUTAIHONG PRECISION INDUSTRY CO., LTD., ShenZhen City (CN)

(21) Appl. No.: 13/116,301

(22) Filed: May 26, 2011

(30) Foreign Application Priority Data
Oct. 11, 2010 (CN) 201010502723.3

(51) Int. Cl. B32B 7/12; B29C 45/14; C23C 16/06; B32B 1/02

(52) U.S. Cl. 428/35.7; 428/34.1; 264/279; 427/250

(57) ABSTRACT

A housing comprises a substrate and a decorative film. The decorative film comprises a transparent film, a metallic coating, a transparent varnish layer, a color layer, a protective layer and an adhesive layer. The metallic coating is formed on an inner surface of the transparent film. The varnish layer is formed on the metallic coating. The color layer is formed on the varnish layer. The protective layer is formed on the color layer. The adhesive layer is formed on the protective layer. The substrate is integrally molded with the decorative film bonding the adhesive layer.

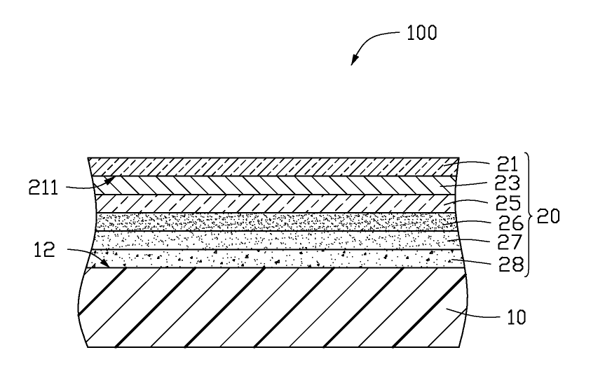

### BACKGROUND

1. Technical Field

The exemplary disclosure generally relates to housings and methods for manufacturing the housings, particularly to housings used in portable electronic devices.

2. Description of Related Art

Currently, portable electronic devices with wireless communication capability, such as mobile phones, are widely used. Often, the housing of a portable electronic device is made of a metallic material. However, metallic housings can interfere with communication signals of the portable electronic device.

Therefore, there is a room for improvement in the art.

### BRIEF DESCRIPTION OF THE DRAWING

Many aspects of the embodiments can be better understood with reference to the following drawing. The components in the drawings are not necessarily drawn to scale, the emphasis instead being placed upon clearly illustrating the principles of the exemplary housing and method of manufacturing the housing. Moreover, in the drawings like reference numerals designate corresponding parts throughout the several views. Wherever possible, the same reference numbers are used throughout the drawings to refer to the same or like elements of an embodiment.

The figure is a schematic cross-sectional view of an exemplary embodiment of the present housing.

### DETAILED DESCRIPTION

The figure shows an exemplary housing 100 including a plastic substrate 10 and a decorative film 20 laminated on an outer surface 12 of the substrate 10. The decorative film 20 includes a transparent film 21, a metallic coating 23, a varnish layer 25, a color layer 26, a protective layer 27, and an adhesive layer 28.

The transparent film 21 is made of transparent plastic, such as polypropylene, polycarbonate, or polymethyl methacrylate.

The metallic coating 23 is directly formed on an inner surface 211 of the transparent film 21. The metallic coating 23 presents a metallic appearance and is at least translucent. The metallic coating 23 is formed by physical vapor deposition and can be nonconductive to avoid blocking electromagnetic waves. The metallic coating 23 may be composed of metal such as indium, aluminum, titanium, tin and chromium. In other embodiments, the metallic coating 23 can be made of non-metal compounds having metallic appearance, such as silicon dioxide and alumina.

The varnish layer 25 is directly formed on the metallic coating 23. The varnish layer 25 is mainly composed of resin and auxiliary agents without any colorant.

The color layer 26 is directly formed on the varnish layer 25. And because of the at least translucent property of the metallic layer 23, the color layer 26 which may be composed of ink is visible to users.

The protective layer 27 is directly formed on the color layer 26. The protective layer 27 may be composed of ink.

The adhesive layer 28 is directly formed on the protective layer 27. The adhesive layer 28 strengthens the bonding of the decorative film 20 and the substrate 10. The adhesive layer 28 may be composed of epoxy resin adhesive, polyurethane resin adhesive, or acrylic resin adhesive.

The substrate 10 is made of thermoplastic material such as polyethylene, polycarbonate, acrylonitrile bivinyl styrene, polymethyl methacrylate, or any combination thereof. The substrate 10 is integrally molded on the decorative film 20, bonding the adhesive layer 28. Thus, the metallic coating 23, varnish layer 25, color layer 26, protective layer 27 and adhesive layer 28 located between the substrate 10 and the transparent film 21.

The transparent film 21 can protect the metallic coating 23 and the color layer 26 from abrasion. The varnish layer 25 between the metallic coating 23 and the color layer 26 strengthens the bonding of the metallic coating 23 and the color layer 26 and prevent the metallic coating 23 from being peeled from the color layer 26. Furthermore, the protective layer 27 between the color layer 26 and the adhesive layer 38 protects the color layer 26 from damages when the substrate 10 is integrally molded to the decorative film 20.

An exemplary method for manufacturing the housing 100 includes steps as following. A decorative film 20 is provided. The decorative film 20 has the transparent film 21 with the metallic coating 23, varnish layer 25, color layer 26, protective layer 27 and adhesive layer 28 formed thereon. The metallic coating 23 is formed by physical vapor deposition, such as sputtering or vacuum evaporation. The varnish layer 25, the color layer 26, the protective layer 27 and the adhesive layer 28 may be formed by spraying or printing. Then, a mold (not shown) corresponding to the housing 100 is provided. The decorative film 20 is laid in the mold, and molten plastic is injected into the mold to form a substrate 10, which is subsequently integrally molded with the decorative film 20 to entirely bonding the adhesive layer 28, accordingly forming the housing 100.

The housing 100 was subjected to cold-hot thermal shock cycle test between −40° C. and 85° C. for 5 cycles with each of the −40° C. and 85° C. points maintained for about 2 hours. No peeling was observed in the layers between the transparent film 21 and the substrate 10.

The housing 100 was subjected to wet thermal shock test between 25° C. and 65° C. for 18 cycles with each of the 25° C. and 65° C. points maintained for about 9 hours. No peeling was observed with the layers between the transparent film 21 and the substrate 10.

It is to be understood, however, that even though numerous characteristics and advantages of the exemplary disclosure have been set forth in the foregoing description, together with details of the structure and function of the disclosure, the disclosure is illustrative only, and changes may be made in detail, especially in matters of shape, size, and arrangement of parts within the principles of the disclosure to the full extent indicated by the broad general meaning of the terms in which the appended claims are expressed.

What is claimed is:

1. A housing, comprising:
a substrate; and
a decorative film, the decorative film comprising a transparent film, a metallic coating, a transparent varnish layer, a color layer, a protective layer and an adhesive layer, the metallic coating formed on an inner surface of the transparent film, the varnish layer formed on the metallic coating, the color layer formed on the varnish layer, the protective layer formed on the color layer, the adhesive layer formed on the protective layer;
wherein the substrate is integrally molded with the decorative film bonding the adhesive layer.

2. The housing as claimed in claim 1, wherein the metallic coating is formed by physical vapor deposition.

3. The housing as claimed in claim 1, wherein the metallic coating is nonconductive and at least translucent.

4. The housing as claimed in claim 1, wherein the metallic coating is composed of material having a metallic appearance.

5. The housing as claimed in claim 4, wherein the material having a metallic appearance is a metal.

6. The housing as claimed in claim 4, wherein the material having a metallic appearance is a nonmetal.

7. The housing as claimed in claim 1, wherein the color layer is composed of ink.

8. The housing as claimed in claim 1, wherein the protective layer is composed of ink.

9. The housing as claimed in claim 1, wherein the substrate is made of thermoplastic.

10. The housing as claimed in claim 1, wherein the transparent film is made of transparent plastic.

11. A method for manufacturing a housing, comprising:
providing a decorative film, the decorative film comprising a transparent film, a metallic coating, a transparent varnish layer, a color layer, a protective layer and an adhesive layer, the metallic coating formed on one surface of the transparent film, the varnish layer formed on the metallic coating, the color layer formed on the varnish layer, the protective layer formed on the color layer, the adhesive layer formed on the protective layer;
integrally injection molding a substrate with the decorative film to bond the adhesive layer.

12. The method as claimed in claim 11, wherein the metallic coating is formed by physical vapor deposition.

13. The method as claimed in claim 11, the metallic coating is nonconductive and at least translucent.

14. The method as claimed in claim 11, wherein the metallic coating is composed of material having a metallic appearance.

15. The method as claimed in claim 14, wherein the material having a metallic appearance is a metal.

16. The method as claimed in claim 14, wherein the material having a metallic appearance is a nonmetal.

17. The method as claimed in claim 11, wherein the varnish layer, color layer, protective layer and adhesive layer are formed by spraying or printing.

18. The method as claimed in claim 11, wherein the color layer and the protective layer both are composed of ink.

19. The method as claimed in claim 11, wherein the substrate is made of thermoplastic.

20. The method as claimed in claim 11, wherein transparent film is made of plastic.
